(19) United States
(12) Patent Application Publication
(10) Pub. No.: US 2017/0175904 A1
(43) Pub. Date: Jun. 22, 2017

(54) RECTANGULAR GATE VACUUM VALVE ASSEMBLY, METHOD FOR OPERATING THE ASSEMBLY AND SEMICONDUCTOR MANUFACTURING APPARATUS INCLUDING THE ASSEMBLY

(71) Applicant: FUGEN CO., LTD., Hwaseong-si (KR)

(72) Inventor: Hee Jun AHN, Pyeongtaek-si (KR)

(21) Appl. No.: 15/302,585

(22) PCT Filed: May 26, 2015
(86) PCT No.: PCT/KR2015/005258

§ 371 Date: Oct. 7, 2016

(30) Foreign Application Priority Data
Apr. 6, 2015 (KR) 10-2015-0048627

(51) Int. Cl. F16K 3/18; F16K 11/044; H01L 21/67; F16K 3/02; F16K 27/04; F16K 51/02; F16K 11/20; F16K 11/052

(52) U.S. Cl. CPC F16K 3/18; F16K 11/20; F16K 11/044; F16K 11/052; F16K 3/0218; F16K 27/044; F16K 51/02; H01L 21/67017

(57) ABSTRACT

There is provided a rectangular gate vacuum valve assembly comprising: a gate frame having an inner space defined therein, wherein the gage frame has opposite side walls and opposite top and bottom walls, wherein the gate frame has opposite first and second gates defined in the opposite side walls respectively, wherein the gate frame has first and second holes defined in the opposite top and bottom walls respectively; a first valve mechanism configured to translate through the first hole into the inner space and/or to rotate in the inner space to selectively open or close the first gate; and a second valve mechanism configured to translate through the second hole into the inner space and/or to rotate in the inner space to selectively open or close the second gate.

### BACKGROUND

Field of the Present Disclosure

The present disclosure relates to a rectangular gate vacuum valve assembly, a method for operating the assembly and a semiconductor manufacturing apparatus including the assembly. More particularly, the present disclosure relates to a rectangular gate vacuum valve assembly to seal opposite first and second gates defined in the same limited space, which may be useful when the opposite first and second gates defined in the same limited space should be sealed for the semiconductor manufacturing process.

Discussion of the Related Art

The semiconductor should be manufactured in a clean room for a high precision.

The semiconductor manufacturing process should be carried out in a vacuum state in order to prevent the semiconductor from being polluted by contaminants in an air.

The semiconductor manufacturing facility may have a gate valve to selectively form a vacuum state in a chamber.

Among various gate valves, a rectangular gate vacuum valve has been generally employed.

The rectangular gate vacuum valve may be applied not only to the semiconductor manufacturing process but also to a LCD manufacturing process. The rectangular gate vacuum valve may be disposed between a process chamber and transfer chamber, or between a transfer chamber and loadlock chamber.

The vacuum valve may be classified into uni-directional and bi-directional valves.

The rectangular gate vacuum valve may open or close a rectangular gate using a disk thereof.

Regarding an operation of the gate vacuum valve, a main shaft with a disk is lifted up into the gate frame (close mode), and is pushed toward to close the gate (push mode), and is withdrawn from the gate frame to open the gate (open mode).

Those close, push and open modes may be repeated to allow or disallow the vacuum sate.

The rectangular gate vacuum valve may be operated by a translation movement and rotation at a highest level.

A currently available rectangular gate vacuum valve is configured to open or close only one side gate at the gate frame.

For example, when opposite both gates are defined in the same limited space of the gate frame, it may be impossible to close and seal the both gates using the currently available rectangular gate vacuum valve.

### PRIOR ART DOCUMENT

### Patent Document

Korean Patent application No. 10-1987-0011712

Korean Patent application No. 10-1998-0040974

Korean Patent application No. 10-2007-0114829

Korean Patent application No. 10-2012-7028963

### SUMMARY

The present disclosure is to provide a rectangular gate vacuum valve assembly to seal opposite first and second gates defined in the same limited space, which may be useful when the opposite first and second gates defined in the same limited space should be sealed for the semiconductor manufacturing process.

The present disclosure is further to provide a method for operating the assembly and a semiconductor manufacturing apparatus including the assembly.

In one aspect, there is provided a rectangular gate vacuum valve assembly comprising: a gate frame having an inner space defined therein, wherein the gage frame has opposite side walls and opposite top and bottom walls, wherein the gate frame has opposite first and second gates defined in the opposite side walls respectively, wherein the gate frame has first and second holes defined in the opposite top and bottom walls respectively; a first valve mechanism configured to translate through the first hole into the inner space and/or to rotate in the inner space to selectively open or close the first gate; and a second valve mechanism configured to translate through the second hole into the inner space and/or to rotate in the inner space to selectively open or close the second gate.

In one implementation, the first valve mechanism comprises: a first disk configured to selectively open or close the first gate; a first shaft coupled to the first disk to translate the first disk; and a first rotation unit coupled to the first shaft to rotate the first shaft.

In one implementation, the second valve mechanism comprises: a second disk configured to selectively open or close the second gate; a second shaft coupled to the second disk to translate the second disk; and a second rotation unit coupled to the second shaft to rotate the second shaft.

In one implementation, each of the first and second disks has a sealing ring attached thereto.

In one implementation, the first and second gates have the same size or different sizes.

In one aspect, there is provided a system for a rectangular gate vacuum valve assembly, the system comprising: the above-defined assembly; a signal generator configured to generate a control signal to allow closing and opening of the first and second gates; and a controller configured to control operations of the first and second valve mechanisms based on the control signal from the signal generator.

In one aspect, there is provided a method for operating the assembly of claim 1, the method comprising: (a) translating, in a tiled manner, a first shaft of the first valve mechanism together with a first disk coupled to the first shaft through the first hole into the inner space; (b) rotating the first shaft together with the first disk using a first rotation unit coupled to the first shaft by a predetermined angle; and (c) air-tightly closing the first gate by pressure-attaching the first disk with a first sealing ring such that the first sealing ring is air-tightly coupled to the gate frame around the first gate.

In one implementation, the method further comprises (d) withdrawing the first valve mechanism from the inner space; (e) translating, in a tiled manner, a second shaft of the second valve mechanism together with a second disk coupled to the second shaft through the second hole into the inner space; (f) rotating the second shaft together with the second disk using a second rotation unit coupled to the second shaft by a predetermined angle; and (g) air-tightly closing the second gate by pressure-attaching the second disk with a second sealing ring such that the second sealing ring is air-tightly coupled to the gate frame around the second gate.

In one implementation, a repetition of the operations (a) to (c) is individual from a repetition of the operations (e) to (g).

In one aspect, there is provided a method for operating a rectangular gate vacuum valve assembly, the method comprising: translating, vertically, a first shaft of a first valve mechanism together with a first disk coupled to the first shaft through a bottom hole of a gate frame into the inner space defined in the gate frame; and translating, horizontally, the first shaft toward a first gate defined in a first side wall of the gate frame, thereby air-tightly closing the first gate by pressure-attaching the first disk with a first sealing ring such that the first sealing ring is air-tightly coupled to the gate frame around the first gate.

In one aspect, there is provided a semiconductor manufacturing apparatus comprising: first and second vacuum chambers spaced from each other where a semiconductor manufacturing process is conducted; and a rectangular gate vacuum valve assembly disposed between the first and second vacuum chambers, wherein the rectangular gate vacuum valve assembly is configured to selectively close or open first and second gates communicating with the first and second vacuum chambers respectively, wherein the rectangular gate vacuum valve assembly comprises: a gate frame having an inner space defined therein, wherein the gage frame has opposite side walls and opposite top and bottom walls, wherein the gate frame has the opposite first and second gates defined in the opposite side walls respectively, wherein the gate frame has first and second holes defined in the opposite top and bottom walls respectively; a first valve mechanism configured to translate through the first hole into the inner space and/or to rotate in the inner space to selectively open or close the first gate; and a second valve mechanism configured to translate through the second hole into the inner space and/or to rotate in the inner space to selectively open or close the second gate.

In one implementation, the first valve mechanism comprises: a first disk configured to selectively open or close the first gate; a first shaft coupled to the first disk to translate the first disk; and a first rotation unit coupled to the first shaft to rotate the first shaft, wherein the second valve mechanism comprises: a second disk configured to selectively open or close the second gate; a second shaft coupled to the second disk to translate the second disk; and a second rotation unit coupled to the second shaft to rotate the second shaft, wherein each of the first and second disks has a sealing ring attached thereto.

### Advantageous Effect

The present rectangular gate vacuum valve assembly may seal the opposite first and second gates 121,122 defined in the same limited space. Thus, this may be useful when the opposite first and second gates 121,122 defined in the same limited space should be sealed for the semiconductor manufacturing process.

### BRIEF DESCRIPTION OF THE DRAWINGS

FIG. 1 is a diagram of a schematic structure of a semiconductor manufacturing apparatus in accordance with one embodiment of the present disclosure wherein a first gate is closed.

FIG. 2 is a diagram of a schematic structure of a semiconductor manufacturing apparatus in accordance with one embodiment of the present disclosure wherein a second gate is closed.

FIG. 3 is a diagram of a schematic structure of the rectangular gate vacuum valve assembly in accordance with one embodiment of the present disclosure.

FIG. 4 to FIG. 7 illustrates operations of the rectangular gate vacuum valve assembly.

FIG. 8 is a block diagram of a system for controlling the rectangular gate vacuum valve assembly.

FIG. 9 is a flow chart of a method for operating the rectangular gate vacuum valve assembly in accordance with one embodiment of the present disclosure.

FIG. 10 to FIG. 13 illustrates variations of the rectangular gate vacuum valve assembly respectively.

### DETAILED DESCRIPTIONS

In one embodiment, there may be provided a rectangular gate vacuum valve assembly comprising: a gate frame having an inner space defined therein, wherein the gage frame has opposite side walls and opposite top and bottom walls, wherein the gate frame has opposite first and second gates defined in the opposite side walls respectively, wherein the gate frame has first and second holes defined in the opposite top and bottom walls respectively; a first valve mechanism configured to translate through the first hole into the inner space and/or to rotate in the inner space to selectively open or close the first gate; and a second valve mechanism configured to translate through the second hole into the inner space and/or to rotate in the inner space to selectively open or close the second gate.

### Embodiments

Examples of various embodiments are illustrated in the accompanying drawings and described further below.

It will be understood that the description herein is not intended to limit the claims to the specific embodiments described. On the contrary, it is intended to cover alternatives, modifications, and equivalents as may be included within the spirit and scope of the present disclosure as defined by the appended claims.

The present disclosure, however, may be embodied in various different forms, and should not be construed as being limited to only the illustrated embodiments herein.

Rather, these embodiments are provided as examples so that this disclosure will be thorough and complete, and will fully convey the aspects and features of the present disclosure to those skilled in the art.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “connected to”, or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present disclosure. As used herein, the singular forms “a” and “an” are intended to include the plural forms as well, unless the context clearly indicates otherwise.

It will be further understood that the terms “comprises”, “comprising”, “includes”, and “including” when used in this specification, specify the presence of the stated features, integers, s, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entire list of elements and may not modify the individual elements of the list.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the following description, numerous specific details are set forth in order to provide a thorough understanding of the present disclosure. The present disclosure may be practiced without some or all of these specific details. In other Instances, well-known process structures and/or processes have not been described in detail in order not to unnecessarily obscure the present disclosure.

Further, the use of “may” when describing embodiments of the present disclosure refers to “one or more embodiments of the present disclosure.”

Hereinafter, embodiments of the present disclosure will be described in details with reference to attached drawings, which are incorporated in and form a part of this specification and in which like numerals depict like elements, illustrate embodiments of the present disclosure and, together with the description, serve to explain the principles of the disclosure.

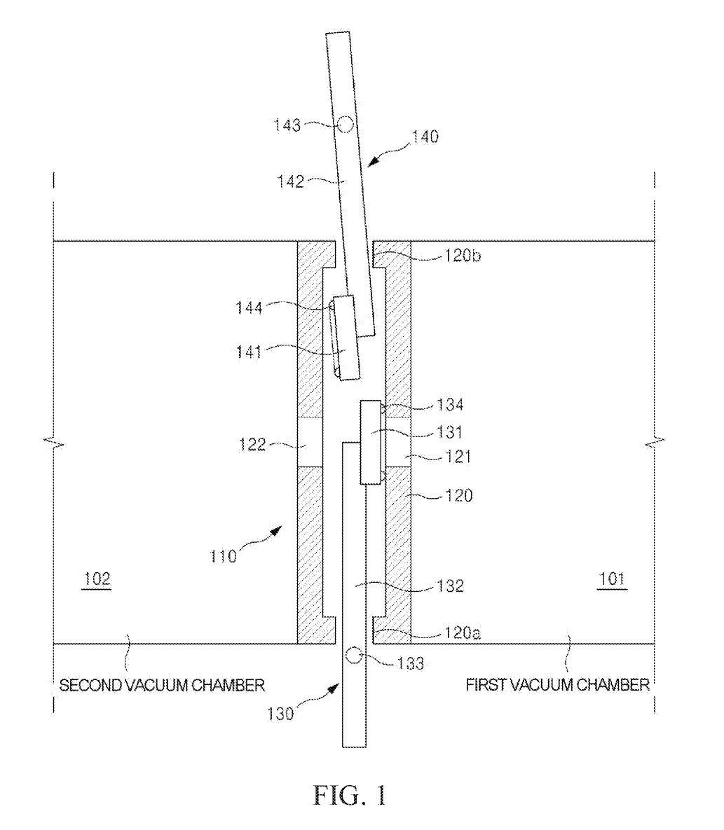

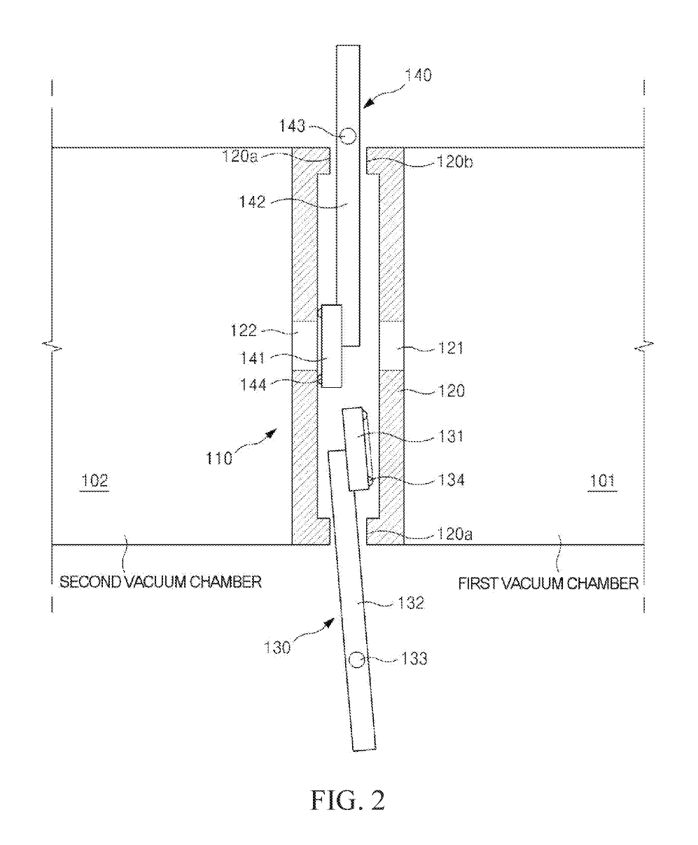

FIG. 1 is a diagram of a schematic structure of a semiconductor manufacturing apparatus in accordance with one embodiment of the present disclosure wherein a first gate is closed. FIG. 2 is a diagram of a schematic structure of a semiconductor manufacturing apparatus in accordance with one embodiment of the present disclosure wherein a second gate is closed.

Referring to FIG. 1 and FIG. 2, the semiconductor manufacturing apparatus in accordance with one embodiment of the present disclosure may include first and second vacuum chambers 101,102 spaced from each other where a semiconductor manufacturing process is conducted; and a rectangular gate vacuum valve assembly 110 disposed between the first and second vacuum chambers 101,102, wherein the rectangular gate vacuum valve assembly 110 may be configured to selectively close or open first and second gates 121,122 corresponding to the first and second vacuum chambers 101,102 respectively.

The first and second vacuum chambers 101,102 may have the same or different functions.

For example, the first and second vacuum chambers 101,102 may be a deposition chamber, a process chamber, a transfer chamber, or a loadlock chamber. The first and second vacuum chambers 101,102 may be used to manufacturing the display panel. The present disclosure may not be limited thereto.

The rectangular gate vacuum valve assembly 110 may be configured to selectively close or open first and second gates 121,122 corresponding to the first and second vacuum chambers 101,102 respectively. The first and second gates 121,122 may be communicated with the first and second vacuum chambers 101,102 respectively.

The rectangular gate vacuum valve assembly 110 may seal the opposite first and second gates 121,122 defined in the same limited space. Thus, this may be useful when the opposite first and second gates 121,122 defined in the same limited space should be sealed for the semiconductor manufacturing process.

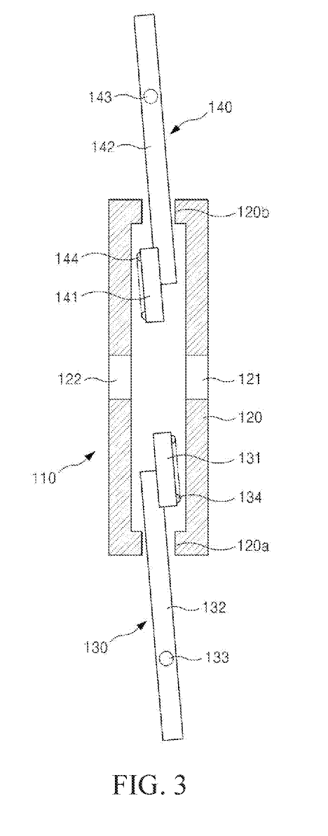

The present rectangular gate vacuum valve assembly 110 will be described in details with reference to FIG. 3 to FIG. 9.

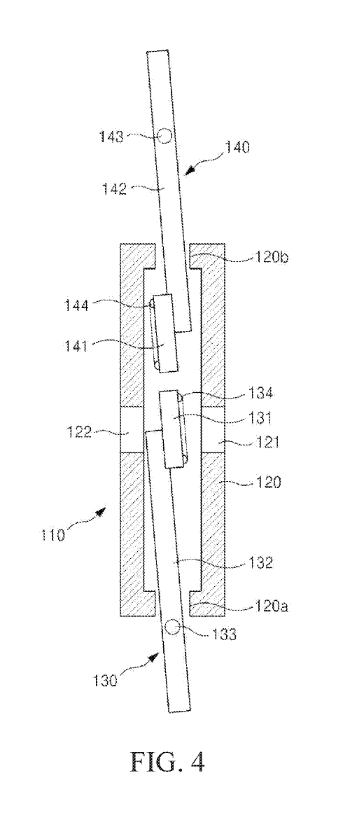

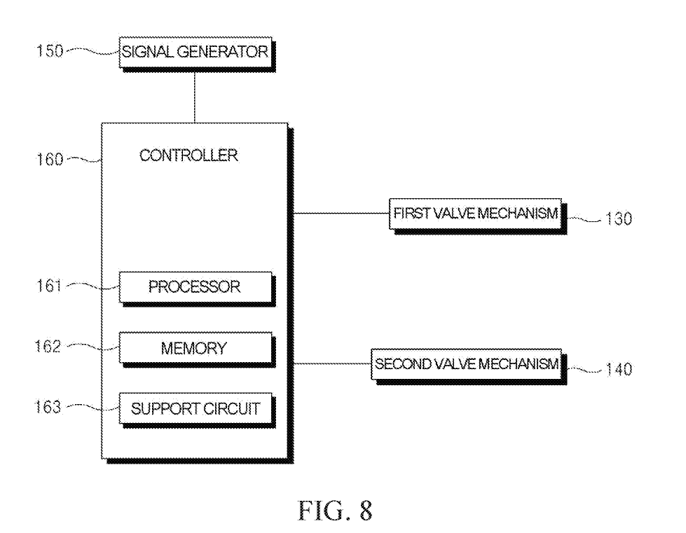

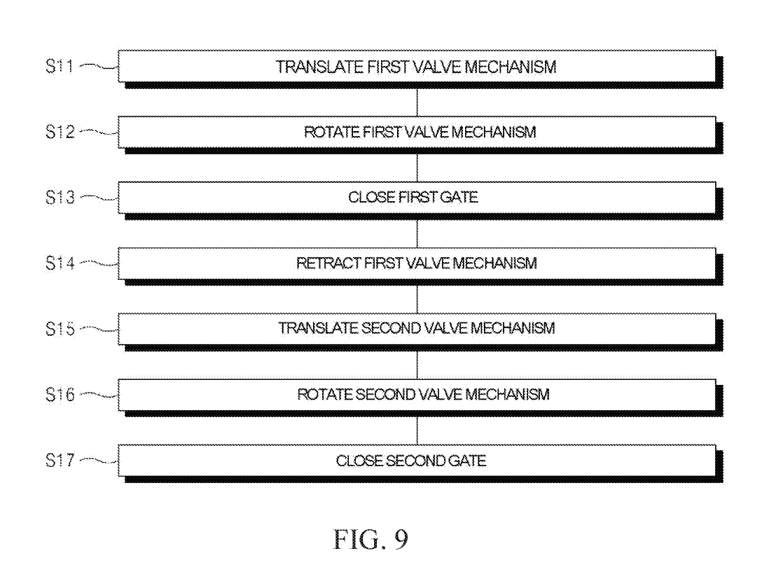

FIG. 3 is a diagram of a schematic structure of the rectangular gate vacuum valve assembly in accordance with one embodiment of the present disclosure. FIG. 4 to FIG. 7 illustrates operations of the rectangular gate vacuum valve assembly. FIG. 8 is a block diagram of a system for controlling the rectangular gate vacuum valve assembly. FIG. 9 is a flow chart of a method for operating the rectangular gate vacuum valve assembly in accordance with one embodiment of the present disclosure.

Referring to FIG. 3 to FIG. 9, the rectangular gate vacuum valve assembly 110 in accordance with one embodiment of the present disclosure may seal the opposite first and second gates 121,122 defined in the same limited space. Thus, this may be useful when the opposite first and second gates 121,122 defined in the same limited space should be sealed for the semiconductor manufacturing process. The rectangular gate vacuum valve assembly 110 in accordance with one embodiment of the present disclosure may include a gate frame 120, a first valve mechanism 130, and a second valve mechanism 140.

The gate frame 120 may be disposed between the first and second chambers 102 and 103. The gate frame 120 may have an inner space defined therein.

The gate frame 120 may have the opposite first gate 121 and second gate 122 defined at opposite walls of the frame 120. Each of the first gate 121 and second gate 122 may have a rectangular shape as viewed from a side.

In one example, the first gate 121 and the second gate 122 may have the same size.

In another example, the first gate 121 and the second gate 122 may have different sizes.

As shown in FIG. 3 to FIG. 5, the first valve mechanism 130 may be configured to translate through a bottom hole 120a defined at a bottom wall of the gate frame 120 into an inner space in the gate frame 120 or to rotate in an inner space in the gate frame 120 to selectively open or close the first gate 121.

The first valve mechanism 130 may include a first disk 131 configured to selectively open or close the first gate 121, a first shaft 132 coupled to the first disk 131 to translate the first disk 131, and a first rotation unit 133 operatively coupled to the first shaft 132 to rotate the first shaft 132.

The first gate 121 may be rectangular, and, hence, the first disk 131 may be rectangular. The first disk 131 may have a size larger than that of the first gate 121.

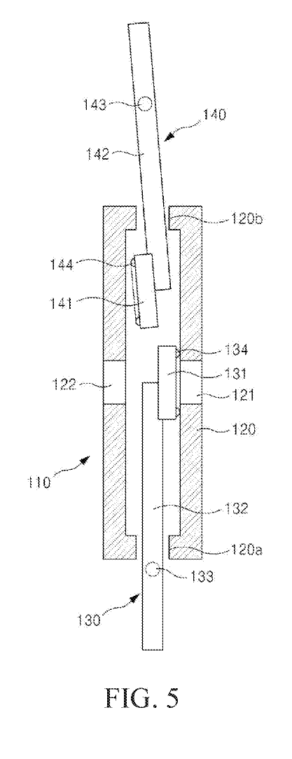

The first disk 131 may have a first sealing ring 134 attached thereto at an outer circumference. Thus, the first sealing ring 134 may be tightly attached to the first gate 121 to keep a vacuum state in the chamber as shown in FIG. 5.

The first shaft 132 may be configured to translate the first disk 131 and the first rotation unit 133 may be configured to rotate the first disk 131. A motor (not shown) may be operatively coupled to the first shaft 132. A motor (not shown) may be operatively coupled to the first rotation unit.

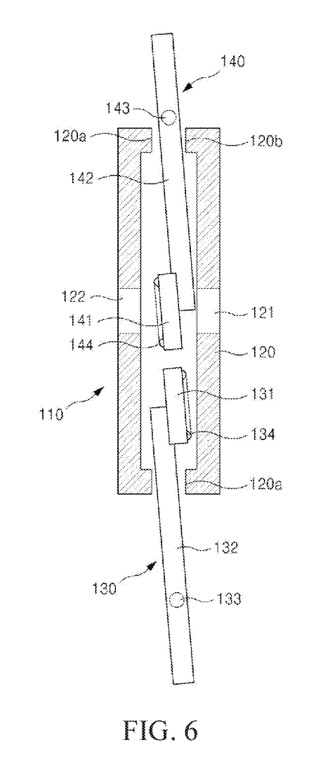

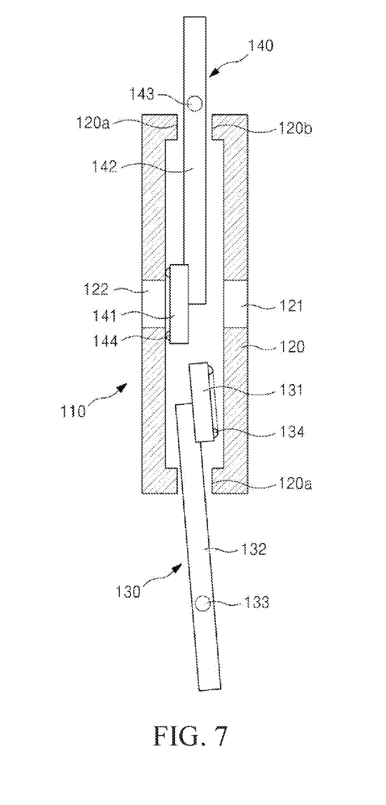

As shown in FIG. 3, FIG. 6 and FIG. 7, the second valve mechanism 140 may be configured to translate through a top hole 120b defined at a top wall of the gate frame 120 into an inner space in the gate frame 120 or to rotate in an inner space in the gate frame 120 to selectively open or close the second gate 122.

The second valve mechanism 140 may include a second disk 141 configured to selectively open or close the second gate 122, a second shaft 142 coupled to the second disk 141 to translate the second disk 141, and a second rotation unit 143 operatively coupled to the second shaft 142 to rotate the second shaft 142.

The second gate 122 may be rectangular, and, hence, the second disk 141 may be rectangular. The second disk 141 may have a size larger than that of the second gate 122.

The second disk 141 may have a second sealing ring 144 attached thereto at an outer circumference. Thus, the second sealing ring 144 may be tightly attached to the second gate 122 to keep a vacuum state in the chamber as shown in FIG. 7.

The second shaft 142 may be configured to translate the second disk 141 and the second rotation unit 143 may be configured to rotate the second disk 141. A motor (not shown) may be operatively coupled to the second shaft 142. A motor (not shown) may be operatively coupled to the second rotation unit.

FIG. 8 is a block diagram of a system for controlling the rectangular gate vacuum valve assembly. The system may include the rectangular gate vacuum valve assembly 110, a signal generator 150 and a controller 160. The signal generator 150 may generate a control signal to control the rectangular gate vacuum valve assembly 110 to close or open the first gate 121 and second gate 122. The control signal may be transfer to the controller 160.

The controller 160 may control an operation of the first valve mechanism 130 and second valve mechanism 140 based on the control signal from the signal generator 150. For example, based on a first control signal from the signal generator 150, the controller 160 may control the operation of the first valve mechanism 130 to close the first gate 121 as shown in FIG. 5. For example, based on a second control signal from the signal generator 150, the controller 160 may control the operation of the second valve mechanism 140 to close the second gate 122 as shown in FIG. 7.

The controller 160 may include a processor 161, a memory 162, and a supporting circuit 163.

The processor 161 may be configured to control the operation of the first valve mechanism 130 and second valve mechanism 140 based on the control signal from the signal generator 150. The processor 161 may be implemented as Complex Instruction Set Computer (CISC) or Reduced Instruction Set Computer (RISC) processors, x86 instruction set compatible processors, multi-core, or any other microprocessor or central processing unit (CPU). In embodiments, the processor 161 may comprise dual-core processor(s), dual-core mobile processor(s), and so forth.

The memory 162 may be coupled to the processor 161. The memory 162 may be implemented as a volatile memory device such as, but not limited to, a Random Access Memory (RAM), Dynamic Random Access Memory (DRAM), or Static RAM (SRAM).

The supporting circuit 163 may be coupled to the processor 161 to support the operation of the processor. The supporting circuit 163 may include a cache, a power supply, a clock circuit, an input/output circuit, and a sub-system.

The processor described in the disclosed embodiment may be implemented as a software routine written in a computer language configured to be executed by a hardware machine (such as C, C++, Fortran, Java, Basic, or the like).

The processor 161 described herein may be implemented by various means. For example, these techniques may be implemented in hardware (one or more devices), firmware (one or more devices), software (one or more modules), or combinations thereof. For a hardware implementation, the apparatus may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, digitally enhanced circuits, other electronic units designed to perform the functions described herein, or a combination thereof.

Hereinafter, operations of the present rectangular gate vacuum valve assembly 110 will be described with reference to FIG. 9.

First, the first shaft 132 of the first valve mechanism 130 together with the first disk 131 may translate through the bottom hole 120a of the gate frame 120 into the inner space in the gate frame 120 in a tilted manner S11.

Then, the first shaft 132 of the first valve mechanism 130 together with the first disk 131 may rotate using the first rotation unit 133 by a predetermined angle S12.

The first disk 131 may be pressed to the first gate 121 and thus the first sealing ring 134 may be air-tightly attached to the first gate 121, thereby to close the first gate 121 S13 (See FIG. 5).

Then, the first valve mechanism 130 may return to an original position S14.

Next, the second shaft 142 of the second valve mechanism 140 together with the second disk 141 may translate through the top hole 120b of the gate frame 120 into the inner space in the gate frame 120 in a tilted manner S15.

Then, the second shaft 142 of the second valve mechanism 140 together with the second disk 141 may rotate using the second rotation unit 143 by a predetermined angle S16.

The second disk 141 may be pressed to the second gate 122 and thus the second sealing ring 144 may be air-tightly attached to the second gate 122, thereby to close the second gate 122 S17 (See FIG. 7).

The operations S11 to S17 may be repeated. The operations S11 to S14 may be triggered by the first control signal from the signal generator 150. The operations S15 to S17 may be triggered by the second control signal from the signal generator 150. A group of the operations S11 to S14 may be individually carried out from a group of the operations S15 to S17.

The rectangular gate vacuum valve assembly 110 in accordance with one embodiment of the present disclosure may seal the opposite first and second gates 121,122 defined in the same limited space. Thus, this may be useful when the opposite first and second gates 121,122 defined in the same limited space should be sealed for the semiconductor manufacturing process.

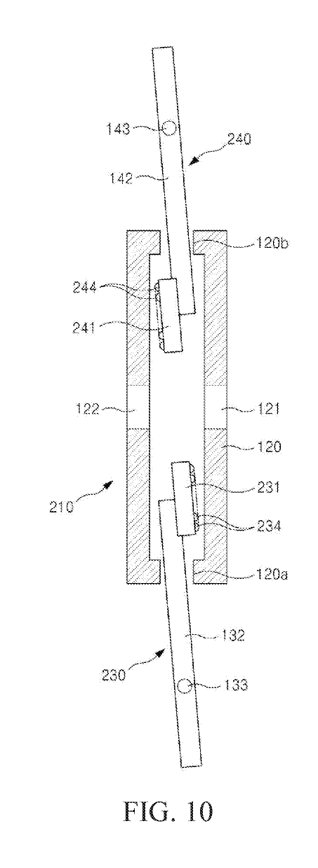

FIG. 10 to FIG. 13 illustrates variations of the rectangular gate vacuum valve assembly respectively.

Referring to FIG. 10, there is shown a rectangular gate vacuum valve assembly 210 wherein first and second valve mechanisms 230, 240 have first and second disks 231, 241 respectively. The first and second disks 231, 241 may have a first pair of sealing rings 234 and a second pair of sealing rings 244 respectively attached thereto.

When the first and second disks 231, 241 have a first pair of sealing rings 234 and a second pair of sealing rings 244 respectively attached thereto, the first and second gates 121,122 may be more reliably closed and sealed, thereby to improve anti-leakage of vacuum.

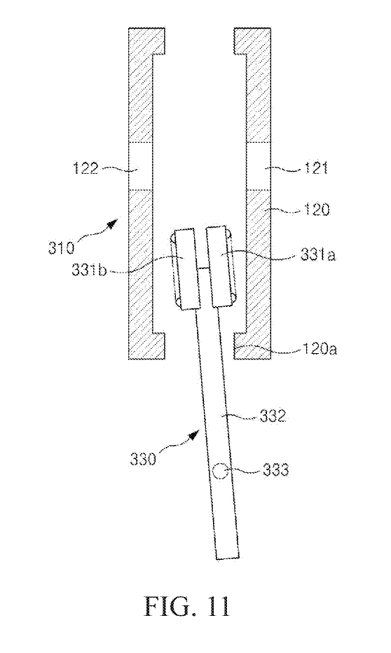

Referring to FIG. 11 to FIG. 13, there is a rectangular gate vacuum valve assembly 310 which may include first and second disks 331a, 331b to open or close the first and second gates 121, 122 respectively; a single common shaft 332 commonly coupled to the first and second disks 331a, 331b to translate the first and second disks 331a, 331b, and a single rotation unit 333 coupled to the common shaft 332 to rotate the common shaft 332.

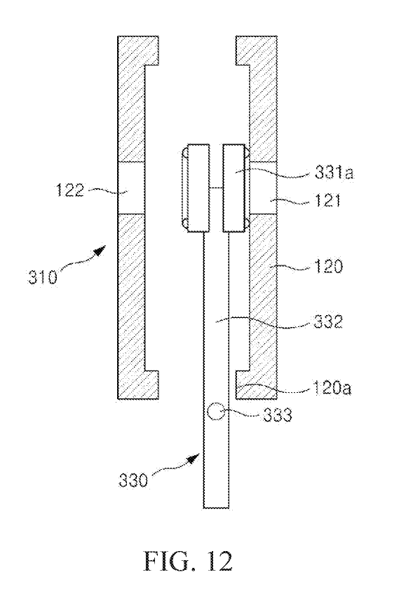

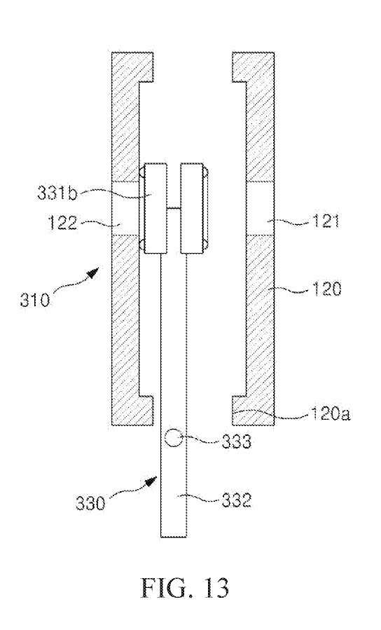

In this way, as shown in FIG. 12 and FIG. 13, using the single common shaft 332 and the single rotation unit 333, the first and second disks 331a, 331b may move selectively toward the first and second gates 121, 122 to close or open the first and second gates 121, 122 respectively. This embodiment may have a simple configuration of the rectangular gate vacuum valve assembly.

The rectangular gate vacuum valve assemblies 120 and 130 as shown in FIG. 10 to FIG. 13 may seal the opposite first and second gates 121,122 defined in the same limited space. Thus, this may be useful when the opposite first and second gates 121,122 defined in the same limited space should be sealed for the semiconductor manufacturing process.

Examples of various embodiments has been illustrated and described above. It will be understood that the description herein is not intended to limit the claims to the specific embodiments described. On the contrary, it is intended to cover alternatives, modifications, and equivalents as may be included within the spirit and scope of the present disclosure as defined by the appended claims.

In order to prevent the conflict between the first valve mechanism and second valve mechanism, the first valve mechanism and second valve mechanism may be operated in an alternate manner.

The above description is not to be taken in a limiting sense, but is made merely for the purpose of describing the general principles of exemplary embodiments, and many additional embodiments of this disclosure are possible. It is understood that no limitation of the scope of the disclosure is thereby intended. The scope of the disclosure should be determined with reference to the Claims. Reference throughout this specification to “one embodiment,” “an embodiment,” or similar language means that a particular feature, structure, or characteristic that is described in connection with the embodiment is included in at least one embodiment of the present disclosure. Thus, appearances of the phrases “in one embodiment,” “in an embodiment,” and similar language throughout this specification may, but do not necessarily, all refer to the same embodiment.

### INDUSTRIAL-ABILITY

The present disclosure may be applied to the gate valve to selectively configure a vacuum environment in the chamber, for example, in the semiconductor manufacturing facility.

What is claimed is:

1. A rectangular gate vacuum valve assembly comprising:
a gate frame having an inner space defined therein, wherein the gage frame has opposite side walls and opposite top and bottom walls, wherein the gate frame has opposite first and second gates defined in the opposite side walls respectively, wherein the gate frame has first and second holes defined in the opposite top and bottom walls respectively;
a first valve mechanism configured to translate through the first hole into the inner space and/or to rotate in the inner space to selectively open or close the first gate; and
a second valve mechanism configured to translate through the second hole into the inner space and/or to rotate in the inner space to selectively open or close the second gate.

2. The assembly of claim 1, wherein the first valve mechanism comprises:
a first disk configured to selectively open or close the first gate;
a first shaft coupled to the first disk to translate the first disk; and
a first rotation unit coupled to the first shaft to rotate the first shaft.

3. The assembly of claim 2, wherein the second valve mechanism comprises:
a second disk configured to selectively open or close the second gate;
a second shaft coupled to the second disk to translate the second disk; and
a second rotation unit coupled to the second shaft to rotate the second shaft.

4. The assembly of claim 3, wherein each of the first and second disks has a sealing ring attached thereto.

5. The assembly of claim 1, wherein the first and second gates have the same size or different sizes.

6. A system for a rectangular gate vacuum valve assembly, the system comprising:
the assembly of claim 1;
a signal generator configured to generate a control signal to allow closing and opening of the first and second gates; and
a controller configured to control operations of the first and second valve mechanisms based on the control signal from the signal generator.

7. A method for operating the assembly of claim 1, the method comprising:
(a) translating, in a tiled manner, a first shaft of the first valve mechanism together with a first disk coupled to the first shaft through the first hole into the inner space;
(b) rotating the first shaft together with the first disk using a first rotation unit coupled to the first shaft by a predetermined angle; and
(c) air-tightly closing the first gate by pressure-attaching the first disk with a first sealing ring such that the first sealing ring is air-tightly coupled to the gate frame around the first gate.

8. The method of claim 7, further comprising:
(d) withdrawing the first valve mechanism from the inner space;
(e) translating, in a tiled manner, a second shaft of the second valve mechanism together with a second disk coupled to the second shaft through the second hole into the inner space;
(f) rotating the second shaft together with the second disk using a second rotation unit coupled to the second shaft by a predetermined angle; and
(g) air-tightly closing the second gate by pressure-attaching the second disk with a second sealing ring such that the second sealing ring is air-tightly coupled to the gate frame around the second gate,
wherein a repetition of the operations (a) to (c) is individual from a repetition of the operations (e) to (g).

9. A method for operating a rectangular gate vacuum valve assembly, the method comprising:
translating, vertically, a first shaft of a first valve mechanism together with a first disk coupled to the first shaft through a bottom hole of a gate frame into the inner space defined in the gate frame; and
translating, horizontally, the first shaft toward a first gate defined in a first side wall of the gate frame, thereby air-tightly closing the first gate by pressure-attaching the first disk with a first sealing ring such that the first sealing ring is air-tightly coupled to the gate frame around the first gate.

10. A semiconductor manufacturing apparatus comprising:
first and second vacuum chambers spaced from each other where a semiconductor manufacturing process is conducted; and
a rectangular gate vacuum valve assembly disposed between the first and second vacuum chambers, wherein the rectangular gate vacuum valve assembly is configured to selectively close or open first and second gates communicating with the first and second vacuum chambers respectively,
wherein the rectangular gate vacuum valve assembly comprises:
a gate frame having an inner space defined therein, wherein the gage frame has opposite side walls and opposite top and bottom walls, wherein the gate frame has the opposite first and second gates defined in the opposite side walls respectively, wherein the gate frame has first and second holes defined in the opposite top and bottom walls respectively;
a first valve mechanism configured to translate through the first hole into the inner space and/or to rotate in the inner space to selectively open or close the first gate; and
a second valve mechanism configured to translate through the second hole into the inner space and/or to rotate in the inner space to selectively open or close the second gate.

11. The apparatus of claim 10, wherein the first valve mechanism comprises:
a first disk configured to selectively open or close the first gate;
a first shaft coupled to the first disk to translate the first disk; and
a first rotation unit coupled to the first shaft to rotate the first shaft,
wherein the second valve mechanism comprises:
a second disk configured to selectively open or close the second gate;
a second shaft coupled to the second disk to translate the second disk; and
a second rotation unit coupled to the second shaft to rotate the second shaft,
wherein each of the first and second disks has a sealing ring attached thereto.
